(19) United States
(12) Patent Application Publication
(10) Pub. No.: US 2017/0279027 A1
(43) Pub. Date: Sep. 28, 2017

(54) THERMOELECTRIC DEVICE FOR A MOTOR VEHICLE

(71) Applicant: Mahle International GmbH, Stuttgart (DE)

(72) Inventors: Thomas Himmer, Reichenbach (DE); Holger Schroth, Maulbronn (DE)

(21) Appl. No.: 15/512,435

(22) PCT Filed: Aug. 5, 2015
(86) PCT No.: PCT/EP2015/068036

§ 371 Date: Mar. 17, 2017

(30) Foreign Application Priority Data
Sep. 18, 2014 (DE) 10 2014 218 787.7

(51) Int. Cl. H01L 35/32

(52) U.S. Cl. CPC H01L 35/32; F01N 5/025

(57) ABSTRACT

A thermoelectric device, for example a thermoelectric generator, for a motor vehicle may include a housing defining a housing interior, and the housing may include a first housing part and a second housing part. The housing may further include a fluid-tight thermally insulating element for thermally insulating at least one first housing part portion of the first housing part from the second housing part. The thermal insulating element may include a separating joint fully encompassing the at least one first housing part portion along a circumferential direction. The separating joint may include at least one opening along the circumferential direction.

### CROSS-REFERENCE TO RELATED APPLICATION

This application claims priority to a German Patent Application No. 10 2014 218 787.7 filed on Sep. 18, 2014, and International Patent Application No. PCT/EP2015/068036 filed on Aug. 5, 2015, the contents of which are hereby incorporated by reference in their entirely.

### TECHNICAL FIELD

The present invention relates to a thermoelectric device, more particularly a thermoelectric generator, for a motor vehicle.

### BACKGROUND

Understood by the term “thermoelectricity” is the reciprocal influencing of temperature and electricity and their conversion into each other. Thermoelectric materials make use of this influencing. However, in order as thermoelectric generators to produce electrical energy from waste heat so-called heat pumps are also utilised if through the use of electrical energy heat is to be transported from a temperature reservoir at a lower temperature into one with a higher temperature.

Known from German patent application DE 10 2014 208 433.4 which was not yet published at the time of the present application is a thermoelectric device of this type, especially for a motor vehicle, comprising a housing which surrounds a first and a second housing part and least partially encompasses a housing interior.

Precisely the cited thermoelectric heat pumps are used in motor vehicle technology for the cooling of a wide variety of different components, such as, for example, modern lithium ion batteries which develop considerable amounts of waste heat. However, such thermoelectric heat pumps can also be used in electric motor vehicles as combined heating and cooling devices, for example for controlling the temperature of the passenger space, especially as they exhibit a considerably higher degree of efficiency than conventional electrical resistance heaters. In motor vehicles with an internal combustion engine, by means of thermoelectric generators the waste heat produced in the exhaust during the combustion process can partly be converted into electrical energy and fed into the on-board network of the motor vehicle. The waste heat converted into electrical energy can thus be utilised to a considerable extent in order to reduce the energy consumption of the motor vehicle to a necessary minimum and thereby prevent the unnecessary emission of waste gases such as CO₂. There are therefore many different areas of application of thermoelectric devices in motor vehicle construction. In each of said areas of application it is of decisive importance to achieve as high a degree of efficiency as possible in order to convert heat into electrical energy or vice versa as effectively as possible.

Thermoelectric devices and/or thermoelectric generators typically comprise a plurality of thermoelectric elements made of a thermoelectrically active material which form the actual thermo-electric module. This thermoelectric module is typically arranged in a housing made of metal as on the one hand a housing of this type has the necessary high degree of thermal conductivity and, on the other hand, it can be very simply assembled and sealed, mostly through joining at least two housing parts to each other by means of a welded connection.

Precisely this fluid-tight fastening of the housing parts of the housing to each other is of considerable importance as the housing interior accommodating the thermoelectric module has to protected against the penetration of various media such as water, exhaust gas, salt etc. As in conventional thermoelectric devices, and in particular in the already cited thermoelectric generators, for the functional creation of a hot and cold side at least two housing parts must be thermally insulated from each other as well as possible, the fundamental problem arises of connecting the housing parts to each other in a manner that is as stable and fluid-tight as possible, as well as thermally insulating.

### SUMMARY

It is therefore the object of the present invention to create an improved embodiment of a thermoelectric device in which the above-described problem is largely, or even completely, eliminated.

This object is solved by the subject matter of the independent patent claims. Preferred forms of embodiment are the subject matter of the dependent patent claims.

The basic concept of the invention is accordingly to provide a thermoelectric device, in particular a thermoelectric generator with a fluid-tight, thermal insulating element which insulates at least one housing part section of a first housing part from a second housing part of the device housing. In this way said housing wall section can be used as the hot side of the thermoelectric device or the thermoelectric generator and the area of the first housing part complementary to the housing wall section as well as the second housing parts can be used as the cold side or vice-versa. Through the fluid-tight design of the thermal insulating element according to the invention it is simultaneously ensured that no unwanted media, such as water, salt or also dirt particles can penetrate into the housing interior delimited by the housing.

A thermoelectric device according to the invention comprises a housing which delimits a housing interior and comprises a first and a second housing part. According to the invention the housing comprises a thermal insulating element for the thermal insulation of at least one housing part portion of the first housing part from the second housing part.

In a preferred form of embodiment the thermal insulating element can be designed as a separating joint which fully surrounds the housing part portion. The separating joint extends along a circumferential direction and along this circumferential direction has at least one opening. Particularly preferably the separating joint can even have several such openings as with an increasing number of openings the thermal conductivity provided by the separating joint decreases. The at least one opening can be designed as a through slit extending along the circumferential direction. In order to provide the insulating element with the required tightness at least one of the openings can be closed in a fluid-tight manner by means of a foil. The foil is preferably made of a metal as in this case it can be particularly easily joined to the casing in order to close the at least one seal. This can be take place, in particular, by means of a soldered or welded connection.

In order to limit the loss of mechanical rigidity associated with an opening to a minimum, in a particularly preferred form of embodiment the separating joint is provided with at least two, preferably with a plurality of openings, which are interrupted by struts integrally formed on the first housing part. By means of such struts the housing part portion to be insulated is connected to the area of the first housing part complimentary thereto. This results in the desired increase in the rigidity of the first housing part.

In a further preferred form of embodiment which can be combined with the previously described forms of embodiment, the first housing part is in the form of a housing pot with a pot base and with a pot collar projecting from the pot base towards the second housing part and encompassing the pot base. In addition, the second housing part is designed as a housing cover which is applied to the pot collar and can close the interior of the housing. In terms of manufacturing such an arrangement with a housing pot and a housing cover is particularly simple to produce and is thus associated with particularly low manufacturing costs.

Particularly expediently the pot base and pot collar can be formed integrally on each other.

Alternatively, however, the pot base and the pot collar can also be separate components which are fastened to each other by means of the thermal insulating element.

In an advantageous further embodiment of the invention the separating joint is arranged in the pot collar and completely encompasses the pot base. In this scenario the separating joint for encompassing the housing part portion of the first housing part extends adjacent to the pot collar along an outer edge section of the pot base. In this way the central area of the pot base is thermally insulated both from the remaining areas of the first housing part as well as the second housing part and can thus be used as a hot or cold side.

In a further preferred form of embodiment the thermal insulating element is a bellows-like structure in the pot cover extending along the circumferential direction and completely encompassing the pot base. By way of such a bellows-like structure thermomechanical stresses in and between the two housing parts occurring as a result of the temperature difference between the hot and cold side can be considerably reduced. Additionally, such a bellows structure exhibits a high thermal resistance and also meets the requirements of the invention with regard to fluid tightness.

To increase the thermal resistance of the bellow-like structure it is proposed to reduce a wall thickness of the pot collar in the region of the bellows-like structure in relation to the wall thickness in the remaining area of the pot collar. In the case of a suitable design of the wall thickness the bellows-like structure can also be provided with resilient properties through which thermo-mechanical stresses in the first housing part can again be reduced.

Particularly expediently the pot collar can project from the pot base essentially at a right angle or at an obtuse or acute angle. In this way the housing interior, which is delimited by the two housing parts, can be used particularly effectively for the arrangement of the thermoelectric module.

In another preferred form of embodiment the two housing parts are in the form of essentially flat housing walls. The thermal insulating element is designed as hollow-cylindrical frame made of a thermally insulating material, in particular a ceramic material. The two end faces of the frame are fastened to the first or the second housing part by means of a bonded connection or adhesive connection.

In a further preferred form of embodiment the thermal insulating element is designed in such a way that it not only thermally insulates one housing part portion of the first housing part from the remaining area of the first housing part complementary thereto, but thermally insulates the entire first housing part from the second housing part. In this way the entire first housing part is available as a hot or cold side of the thermoelectric device or the thermoelectric generator.

In an advantageous further development of the invention not only the first housing part but also the second housing part is provided with a pot base and a pot collar which projects away from the pot base towards the first housing part and encompasses the pot base. In this form of embodiment the two pot collars can be arranged at a distance from one another so that between the two pot collars an opening is formed which fluidically connects the housing interior with the outside environment. However, this opening is closed in a fluid-tight manner by a metallic foil. It is conceivable to apply the metallic foil to the two pot collars by way of a soldered connection or another suitable bonded connection.

In another preferred form of embodiment which is associated with particularly low manufacturing costs an inner side of the pot collar of the first housing part is fastened by means of a bonded connection to an outer side of the pot collar of the second housing part or vice-versa. Alternatively an adhesive connection can also be considered in order to attach the two pot collars to each other.

Particularly stable mechanical connection of the two housing parts to each other can be achieved if the pot collar of the first and/or the second housing part merges into a flange section projecting outwards from the pot collar and arranged essentially in parallel to the pot base.

Other important features and advantages of the invention are set out in the sub-claims, the drawings and the associated description of the figures of the drawings.

The features cited above and the features still to be explained below are of course not only usable in the combinations indicated in each case, but also in other combinations or alone without departing from the framework of the present invention.

Preferred examples of embodiment of the invention are shown in the drawings and will be explained in more detail in the following description wherein the same reference symbols relate to identical or similar or functionally identical components.

### BRIEF DESCRIPTION OF THE DRAWINGS

In each case:

FIGS. 1 to 12 schematically show various examples of thermoelectric devices according to the invention.

### DETAILED DESCRIPTION

Roughly schematically and in longitudinal section, FIG. 1 shows a first example of a thermoelectric device 1 according to the invention. The device 1 comprises a housing 2 with a first housing part 3a and a second housing part 3b. The housing 2 delimits a housing interior 4 in which a thermoelectric module 5 is arranged in a manner known to the relevant person skilled in the art. This comprises a plurality of thermoelectric elements 6 made of a thermoelectrically active material such a bismuth telluride, for example, which are arranged adjacent to each other in the housing interior 4 and are electrically connected to each other by means of electrically conducting conductor bridges 7. The thermoelectric elements 6 are attached to the first or second housing part 3a, 3b via a first or second electrical insulator 7a, 7b made of an electrically isolating, but thermally conducting material, so that the first housing part 3a can act in a known manner as a hot side and the second housing part 3b as a cold side, or vice-versa.

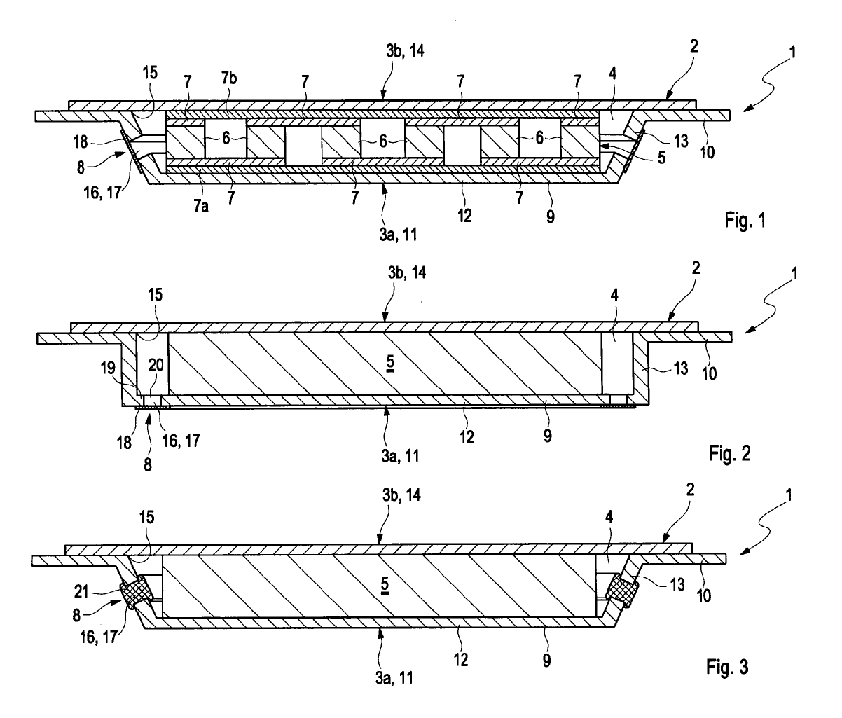

The detailed technical implementation of the thermoelectric module 5 is not the key point of the invention described here and will not be explained in more detail below. In FIGS. 2 to 12, for reasons of clarity the thermoelectric module 5 of FIG. 1 is only shown in the form of a quadrilateral rectangle which is given reference number 5.

The housing 2 has a fluid-tight thermal insulating element 8 by means of which a housing part portion 9 of the first housing part 3a is thermally insulated from the area 10 of the housing part 3a complementary to the housing part portion 9 as well as from the second housing part 3b.

Here, “thermally insulating” is understood to mean that the thermal insulating device 8 has greatly increased thermal resistance compared with the housing parts 3a, 3b so that thermal interaction of the thermally insulated housing part portion 9 with the remaining housing part portions is at least greatly reduced, ideally even completely stopped.

According to FIG. 1 the first housing part 3a is designed as a housing pot 11 with a pot base 12 and with a pot collar 13 projecting from the pot base 12 towards the second housing section 3b. In the example in FIG. 1 the pot base 12 and the pot collar 13 are formed integrally on each other. The pot collar 13 encompasses the pot base 12. In contrast the second housing part 3b is designed as a pot cover 14 which is applied on the pot collar 13 of the first housing part 3a and closes an opening 15 of the first housing part 3a or the housing pot 11 encompassed by the pot collar 13.

As can also been seen from FIG. 1 the thermal insulating element 8 is designed as a separating joint 16 completely encompassing housing section portion 9. The separating joint 16 extends along a circumferential direction and along this circumferential direction has an opening 17 which is closed in a fluid-tight manner by means of a foil 18 made of metal. For this the foil 18 is connected to the two housing parts 3a, 3b in bonded or adhesive manner. In FIG. 1 the separating joint 16 has precisely one opening 17 in the form of a circumferential slit running along the pot collar 13.

In a variant of the example of FIG. 1 shown in FIG. 2 the separating joint along the circumferential direction has a plurality of openings 17 which are interrupted by struts 20. In addition, the example in FIG. 2 differs from that in FIG. 1 in that the thermal insulating element 8 in the form of a separating joint 16 is not arranged in the pot collar 13 but in the pot base 12. To encompass the housing part portion 9 the separating joint 16 thus extends adjacently to the pot collar 10 along an outer edge section 19 of the pot base 12.

By means of the struts 20 the housing part portion 9 is connected to the area 10 of the first housing part 3a complementary thereto. As shown in FIG. 2 the struts can be designed as separate components which are connected to the two housing parts 3a, 3b by adhesion or by means of a bonded connection. Alternatively, however, the struts 20 can also be integrally formed on the first housing part 3a. In this scenario it is conceivable that to produce such struts the openings 17 are punched out of the first housing part 3a.

FIG. 3 shows a further variant of the example of FIG. 1. In this example the separating joint 16 has precisely one opening 17, provided in the pot collar 13 and completely surrounding the pot base 12, which is closed in a fluid-tight manner by way of an adhesive or a sealing element, more particularly made of an elastomer, or a plug part or a sealing mass—all these component are designated 21 in FIG. 3. In a further variant it is also conceivable to combine the variants in FIGS. 2 and 3, which means that several openings 17, interrupted by struts 20, are closed in a fluid-tight manner with the components 21.

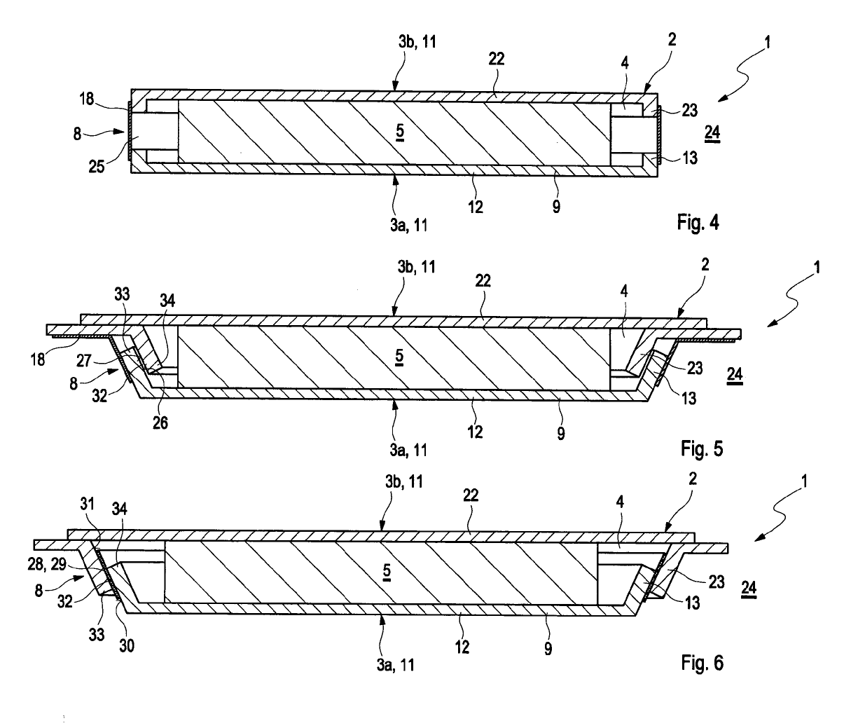

In the example of FIG. 4 the second housing part 3b also has a pot base 22 and a pot collar 23 which encompasses the pot base 22 and projects away from the pot base 22 towards the first housing part 3a. As FIG. 4 clearly shows the two pot collars 13, 23 are arranged at a distance from one another. Between the two pot collars 13, 33 there is an opening 25 which fluidically connects the housing interior 4 with the external environment 24 and which is part of the thermal insulating element 8. The opening 25 can be designed in an analogue manner to the separating joint 16 according to FIGS. 1 to 3 so that the explanations relating to the separating joint 15 with reference to FIGS. 1 and 3 expressly also apply to the variant in FIG. 4. In the example in FIG. 4 the opening 25 is closed in a fluid-tight manner by means of a metallic foil 18 fastened at the end of the two housing parts 3a, 3b by way of a soldered connection.

In the example in FIG. 5 the pot collar 23 is produced separately from the second housing part 3b. The pot collar 23 can be fastened to the pot base 22 of the second housing part by means of a bonded connection. In accordance with FIG. 5 one end section 33 of the pot collar 13 overlaps with an end section 34 of the pot collar 23. The two pot collars 13, 23 are dimensioned in such a way that between an outer side 27 of the pot collar 23 and an inner side 26 of the pot collar 13 a circumferential intermediate space 32 is formed which brings about the desired thermal insulation. The intermediate space 32 is closed or covered in a fluid-tight manner by a metal foil 18 which is soldered onto the outside of the two pot collars 13, 23. Outer side 27 of the pot collar 23 is fastened of the second housing part 3b. In the sample in FIG. 5 said metal foil 18 in synergy with the intermediate space 32 forms the thermal insulating element.

The example in FIG. 6 differs from the example according to FIG. 5 in that an outer side 30 of the pot collar 13 of the first housing part 3a is attached by means of a bonded connection 28 or an adhesive connection 29 to an inner side of the pot collar 23 of the second housing part 3b. The bonded connection 28 or the adhesive connection 29 thus closes the circumferentially formed intermediate space 32 between the end sections 33, 34 of the pot collars. In the example in FIG. 5 the bonded connection 28 or the adhesive connection 29 in synergy with the intermediate space 32 forms the thermal insulating element 8.

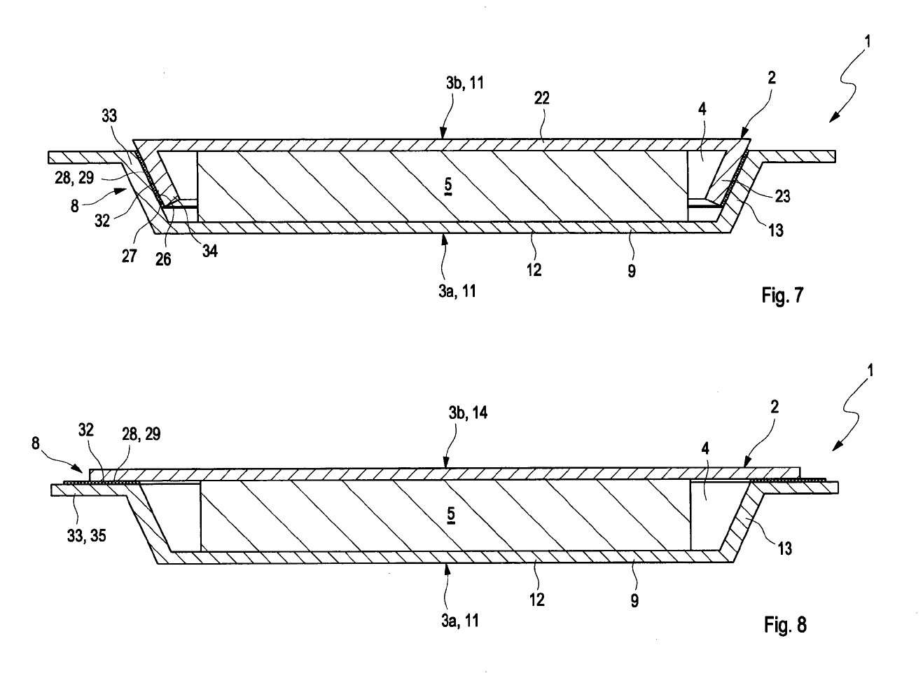

The example in FIG. 7 shows a combination of the examples of FIGS. 5 and 6. According to this pot collar 23 is integrally formed on the pot base 13 of the second housing part 3b. The outer side 27 of the pot collar 23 is opposite the inner side 26 of the pot collar 13 so that between these the intermediate space is formed 32. The inner side 26 of the pot collar 13 of the first housing part 3a is attached by means of a bonded connection 28 or an adhesive connection 29 to the outer side 27, 31 of the pot collar 23 of the second housing part 3b. In an analogue manner to the example in FIG. 6, the bonded connection 28 or the adhesive connection 29 closes the circumferential intermediate space 32 formed between the end sections 33, 34 of the pot collars 13, 23 in a fluid-tight manner. The thermal insulation element 8 is thus formed by the bonded connection 28 or the adhesive connection and the intermediate space 32 closed by these.

FIG. 8 illustrates a further variant in which from the pot base 12 the pot collar 13 of the first housing part 3a merges into a flange section 35 projecting away from the pot collar 12 and arranged essentially in parallel to the pot base 12. An intermediate space 32 between the flange section 35 and the second housing part 3b produced as a housing cover 14 is closed by means of a bonded connection 28 or the adhesive connection 29 between the end section 35 and the housing cover 14 and is in this way sealed in a fluid-tight manner. The thermal insulating element 8 is formed by the bonded connection 28 or the adhesive connection 29 and the intermediate space 29 closed by these.

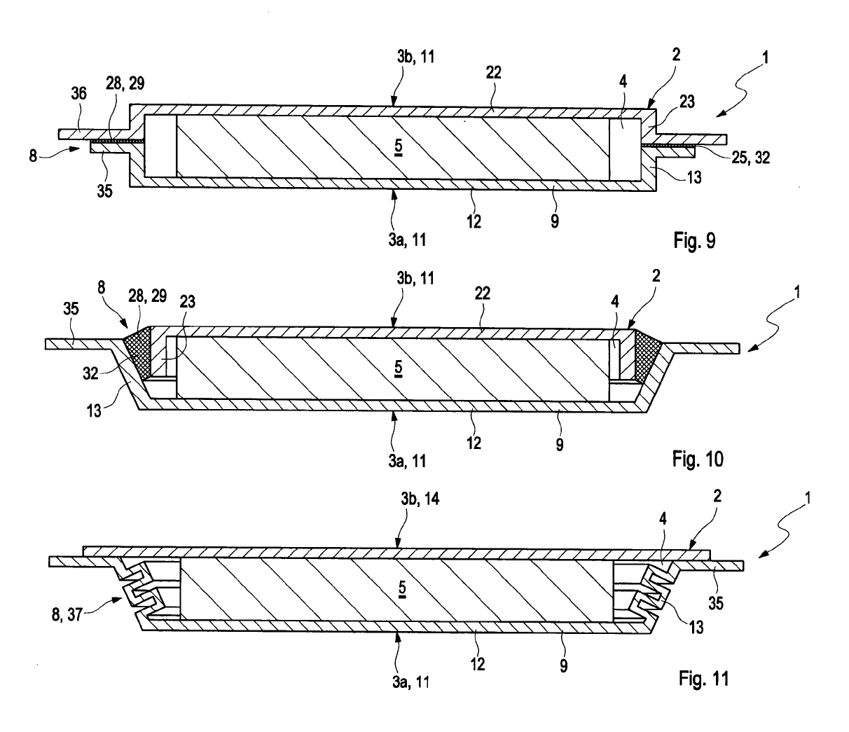

FIG. 9 shows a combination of the variants of FIGS. 4 and 8. In the example in FIG. 9 both pot collars 23, 33 have flange sections 35, 36 projecting outwards between which an intermediate space 32 or an opening 25 between the two pot collars 13, 23 by means of a bonded connection 28 or an adhesive connection 29 between the two pot collars 13, 23. In this way the housing interior 4 is also sealed off against the external environment 24 of the housing 2 and is sealed in this way. The thermal insulating element 8 is formed by the bonded connection 38 or the adhesive connection and the intermediate space 32 closed by these.

The variant in FIG. 10 differs from the variant in FIG. 7 in that the pot collar 23 of the second housing part 3b projects orthogonally from the pot base 22. In contrast the pot collar 13 of the first housing part 3a projects, like the example in FIG. 7, at an obtuse angle from the housing pot 12 of the first housing part 3a. This produces an enlarged intermediate space 32 between the two pot collars 13, 23. More volume for the material of the bonded connection 28—typically soldering tin—or the adhesive connection—typically adhesive—is thus available.

In the example in FIG. 11 the thermal insulating element 8 comprises a bellows-like structure 37 extending along the circumferential direction in the pot collar 13 of the first housing part 13 and completely encompassing the pot base 12. In the area of the bellows-like structure a wall thickness of the pot collar 13 can be reduced compared with a wall thickness in the remaining areas of the pot collar 13 and/or of the pot base 12 complementary to the bellow-like structure.

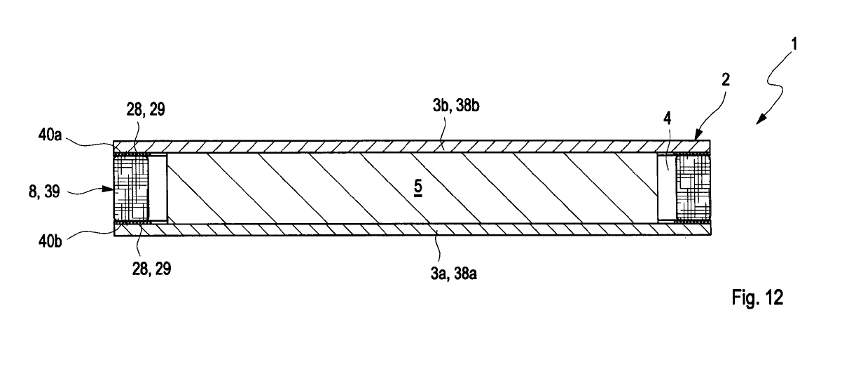

Finally attention is also drawn to the illustration in FIG. 12. In the example in FIG. 12 both housing parts 3a, 3b of the housing 2 are designed as essentially flat housing walls 38a, 38b. In this scenario the thermal insulating element 8 is in the form of a hollow cylindrical frame 39 made of an insulating material, more particular of a ceramic material. The two face ends 40a, 40b of the frame 39 facing the two housing walls 38a, 39b are respectively attached to the first and the second housing part 3a, 3b by means of a bonded connection 29 or an adhesive connection 29.

1. A thermoelectric device for a motor vehicle, comprising:
a housing defining a housing interior and including a first housing part and a second housing part;
the housing further including a fluid-tight thermally insulating element for thermally insulating at least one first housing part portion of the first housing part from the second housing part;
the thermal insulating element includes a separating joint fully encompassing the at least one first housing part portion along a circumferential direction; and
wherein the separating joint includes at least one opening along the circumferential direction.

2. The thermoelectric device according to claim 1, wherein the separating joint has precisely one opening that is closed in a fluid-tight manner via at least one of a metal foil, an adhesive a sealing element, and a plug part.

3. The thermoelectric device according to claim 1, wherein the separating joint includes a plurality of openings and at least one of the plurality of openings is interrupted by a least one strut; and
the at least one strut connects the at least one first housing part portion to an area of the first housing part disposed complementary thereto.

4. The thermoelectric device according to claim 1, wherein:
the first housing part is structured as a housing pot including a pot base and a pot collar projecting from the pot base towards the second housing part and encompassing the pot collar; and
the second housing part is structured as a housing cover coupled to the pot collar.

5. The thermoelectric device according to claim 4, wherein the separating joint extends in the pot collar and completely encompasses the pot base.

6. The thermoelectric device according claim 4, wherein:
the separating joint is arranged in the pot base so that the at least one first housing part portion is an area of the pot base; and
the separating joint extends adjacent to the pot collar along an outer edge section of the pot base to encompass the at least one first housing part portion.

7. The thermoelectric device according to claim 4, wherein the thermal insulating element further includes a bellows-like structure extending in the pot collar along the circumferential direction and completely encompassing the pot base.

8. The thermoelectric device according to claim 7, wherein a wall thickness of the pot collar in an area of the bellows-like structure is reduced in comparison with a wall thickness in an area of the pot collar complementary to the bellows-like structure.

9. The thermoelectric device according to claim 1, wherein:
the first housing parts and the second housing part are structured as essentially flat housing walls;
the thermal insulating element further includes a hollow cylindrical frame composed of a thermally insulating material; and
the frame includes two face ends secured via at least one of a bonded connection an adhesive connection to at least one of the first housing part and the second housing part.

10. The thermoelectric device according to claim 1, wherein the thermal insulating element further thermally insulates the entire first housing part from the second housing part.

11. The thermoelectric device according to claim 4, wherein:
the second housing part further includes a pot base and a pot collar encompassing the pot base and projecting away from the pot base towards the first housing part;
the pot collar of the first housing part and the pot collar of the second housing part are arranged a distance from one another to define an opening therebetween that fluidically connects the housing interior to an external environment; and
the opening is closed in a fluid-tight manner via at least one of a metal foil, a bonded connection, and an adhesive connection.

12. The thermoelectric device according to claim 11, wherein an inner side of the pot collar of one of the first housing part and the second housing part is secured via at least one of a bonded connection and an adhesive connection to an outer side of the pot collar of the other of the first housing part and the second housing part to close an intermediate space present between the pot collar of the first housing part and the pot collar of the second housing part in a fluid-tight manner.

13. The thermoelectric device according to claim 4, the pot collar of the first housing part merges from the pot base into a flange section projecting outwards from the pot collar and arranged essentially parallel to the pot base.

14. The thermoelectric device according to claim 1, wherein the thermal insulating element further includes at least one of a bonded connection an adhesive connection of thermally insulating plastic connecting the first housing part with the second housing part.

15. The thermoelectric device according to claim 4, wherein the pot collar of the first housing part projects from the pot base essentially at one of right angles, an obtuse angle, and an acute angle.

16. The thermoelectric device according to claim 1, wherein the first housing part is structured as a first housing pot including a first pot base and a first pot collar projecting from the first pot base towards the second housing part and encompassing the first pot collar;
wherein the second housing part is structured as a second housing pot including a second pot base and a second pot collar projecting from the second pot base towards the first housing part and encompassing the second pot collar; and
wherein the first pot collar of the first housing part is coupled to the second pot collar of the second housing part.

17. The thermoelectric device according to claim 16, wherein at least one of the first pot collar and the second pot collar merges into an outwardly projecting flange section.

18. The thermoelectric device according to claim 16, wherein the thermal insulating element further includes at least one of a bonded connection and an adhesive connection connecting the first pot collar of the first housing part with the second pot collar of the second housing part.

19. The thermoelectric device according to claim 9, wherein the thermally insulating material of the frame includes a ceramic material.

20. A thermoelectric generator for a motor vehicle, comprising:
a housing defining a housing interior and including a first housing part and a second housing part;
a fluid-tight thermally insulating element disposed to thermally insulate at least one first housing part portion of the first housing part from the second housing part;
the thermal insulating element including a separating joint fully encompassing the at least one first housing part portion along a circumferential direction, wherein the separating joint includes at least one opening along the circumferential direction; and
wherein at least one of the first housing part and the second housing part is structured as a housing pot including a pot base and a pot collar projecting from the pot base towards the other of the first housing part and the second housing part.
